(19) United States
(12) Patent Application Publication
(10) Pub. No.: US 2024/0304590 A1
(43) Pub. Date: Sep. 12, 2024

(54) SEMICONDUCTOR DEVICE

(71) Applicant: DENSO CORPORATION, Kariya-city (JP)

(72) Inventor: MASAKAZU WATANABE, Kariya-city (JP)

(21) Appl. No.: 18/669,914

(22) Filed: May 21, 2024

Related U.S. Application Data
(63) Continuation of application No. PCT/JP2022/046879, filed on Dec. 20, 2022.

(30) Foreign Application Priority Data
Feb. 4, 2022 (JP) 2022-016678

(51) Int. Cl. H01L 23/00; H01L 23/31; H01L 23/367

(52) U.S. Cl. CPC H01L 24/48; H01L 23/3142; H01L 23/3675; H01L 2224/48175; H01L 2224/48482; H01L 2924/13055; H01L 2924/13091

(57) ABSTRACT

A semiconductor device includes a semiconductor element and a terminal substrate. The semiconductor element has a main electrode and a control electrode on a first main surface. The terminal substrate has a bonding terminal to which a wire is to be bonded on a front surface and a relay terminal on a back surface. The bonding terminal and the relay terminal are electrically connected to each other. The bonding terminal has an area larger than an area of the control electrode. The terminal substrate is bonded to the semiconductor element so that the relay terminal and the control electrode are in contact with each other. The terminal substrate has a step on the back surface, and a side surface of the semiconductor element is in contact with the step.

### CROSS REFERENCE TO RELATED APPLICATIONS

The present application is a continuation application of International Patent Application No. PCT/JP2022/046879 filed on Dec. 20, 2022, which designated the U.S. and claims the benefit of priority from Japanese Patent Application No. 2022-016678 filed on Feb. 4, 2022. The entire disclosures of all of the above applications are incorporated herein by reference.

### TECHNICAL FIELD

The present disclosure relates to a semiconductor device.

### BACKGROUND

There is a semiconductor device in which a main electrode and a control electrode are provided on one main surface of a semiconductor element. Such a semiconductor device is, for example, a power semiconductor device for power conversion. In the power semiconductor device, since a current, which is smaller than a current flowing through the main electrode, flows through the control electrode, the area of the control electrode is smaller than the area of the main electrode. In such a semiconductor device, a metal block is connected to the main electrode, and a wire is bonded to the control electrode.

For example, there is a semiconductor device having a wiring sheet attached to one main surface of a semiconductor element. The wiring sheet has an electrode terminal connected to a main electrode and a control terminal connected to a control electrode on one of main surfaces.

### SUMMARY

The present disclosure describes a semiconductor device including a semiconductor element and a terminal substrate. According to an aspect, the semiconductor element has a main electrode and a control electrode on a first main surface. The terminal substrate has a bonding terminal to which a wire is to be bonded on a front surface and a relay terminal on a back surface. The bonding terminal and the relay terminal are electrically connected to each other. The bonding terminal has an area larger than an area of the control electrode. The terminal substrate is bonded to the semiconductor element so that the relay terminal and the control electrode are in contact with each other. The terminal substrate has a step on the back surface, and a side surface of the semiconductor element is in contact with the step.

### BRIEF DESCRIPTION OF THE DRAWINGS

Features and advantages of the present disclosure will become more apparent from the following detailed description made with reference to the accompanying drawings, in which:

FIG. 1 is a perspective view of a semiconductor device according to a first embodiment;

FIG. 2 is an exploded perspective view of the semiconductor device from which a resin package is removed;

FIG. 3 is an explanatory perspective view of a semiconductor element and a terminal substrate of the semiconductor device;

FIG. 4 is a plan view of the semiconductor device in which the resin package and an upper heat dissipation plate are removed;

FIG. 5 is a cross-sectional view taken along a line V-V in FIG. 4;

FIG. 6 is a perspective view of a terminal substrate of a first modification;

FIG. 7 is a perspective view of a terminal substrate of a second modification; and

FIG. 8 is a cross-sectional view of a semiconductor device equipped with the terminal substrate of the second modification.

### DETAILED DESCRIPTION

To begin with, a relevant technology will be described only for understanding the embodiments of the present disclosure.

For example, a semiconductor device, such as a power semiconductor device for power conversion, has a main electrode and a control electrode on one surface of a semiconductor element. Since a smaller current flows in the control electrode than in the main electrode, an area of the control electrode is smaller than an area of the main electrode. In such a semiconductor device, a metal block is connected to the main electrode, and a wire, such as a bonding wire is bonded to the control electrode. The bonding wire is often made of aluminum, and has a diameter of about 500 μm.

As another example, there is a semiconductor device having a wiring sheet attached to a main surface of a semiconductor element on one side. The wiring sheet has an electrode terminal connected to a main electrode and a control terminal connected to a control electrode on one of main surfaces. A copper member is provided inside the wiring sheet, and one end of the copper member is connected to the control terminal. The other end of the copper member is connected to a control electrode terminal, and the control electrode terminal extends out from the wiring sheet. Since the control electrode of the semiconductor element is connected to the copper member through the control terminal on the wiring sheet rather than the wire, the distance between the main electrode and the control electrode can be shortened. For example, a flexible printed circuit board is used for the wiring sheet.

Since only a smaller current flows through the control electrode, the control electrode may be significantly smaller than the main electrode in terms of current capacity. However, in such a semiconductor device described above, the wire (bonding wire) is bonded to the control electrode. In order to bond the wire, the control electrode needs a larger area than the cross-sectional area of the wire. However, if the control electrode is enlarged only for the bonding of the wire, an area of the main surface of the semiconductor element will be enlarged unnecessarily. If the area of the control electrode can be reduced, the area of the main surface of the semiconductor element, that is, the external dimensions of the semiconductor element can be reduced. Since SiC substrates and GaN substrates, which have been attracting attention in recent years, are expensive, the reduction of the area of the main surface results in the reduction of the cost of the semiconductor device.

In the semiconductor device having the wiring sheet, the area of the control electrode can be reduced, and the area of the main surface of the semiconductor element can be reduced accordingly. However, if a flexible wiring sheet is used as the wiring sheet, it is difficult to align the terminal of the wiring sheet to the control electrode of the semiconductor element. The control electrode of the semiconductor element requires an area large enough to allow for a positional error with respect to the terminal on the wiring sheet.

The present disclosure provides a semiconductor device which is capable of reducing the area of a control electrode.

According to an aspect of the present disclosure, a semiconductor device includes a semiconductor element and a terminal substrate. The semiconductor element is provided with a main electrode and a control electrode on a first main surface. The terminal substrate has a bonding terminal to which a wire is to be bonded on a front surface thereof, and a relay terminal on a back surface thereof. The bonding terminal and the relay terminal are electrically connected to each other. The terminal substrate is bonded to the semiconductor element so that the relay terminal is in contact with the control electrode. The bonding terminal has an area larger than the area of the control electrode. Further, the terminal substrate is formed with a step on the back surface, and a side surface of the semiconductor element is in contact with the step.

Since the bonding terminal to which a wire is bonded is provided on the board separate from the semiconductor element, that is, on the terminal substrate, the control electrode on the main surface can be made smaller. Since the side surface of the semiconductor element is brought into contact with the step on the back surface of the terminal substrate, the position of the terminal substrate relative to the semiconductor element can be determined accurately. Therefore, the positional error between the control electrode of the semiconductor element and the relay terminal of the terminal substrate can be reduced, and the control electrode can be made smaller accordingly.

For example, the step may be configured as follows. The terminal substrate has a thin plate portion including the relay terminal and a thick plate portion including the bonding terminal. The thickness of the thin plate portion is smaller than the thickness of the thick plate portion. The step is provided by the boundary between the thin plate portion and the thick plate portion on the back surface of the terminal substrate. The thin plate portion is bonded to the semiconductor element. The back surface of the thick plate portion of the terminal substrate may be flush with a second main surface of the semiconductor element. If there is a flat surface under the semiconductor element and the thick plate portion, both the semiconductor element and the thick plate portion can be supported by the flat surface. In such a case, therefore, the semiconductor element and the thick plate portion will not shift in the thickness direction when the wire is bonded to the bonding terminal.

As another example, a protrusion may be provided on the back surface of the terminal substrate, and the protrusion may form the step.

Details and further improvements provided by the present disclosure will be further explained hereinafter.

### First Embodiment

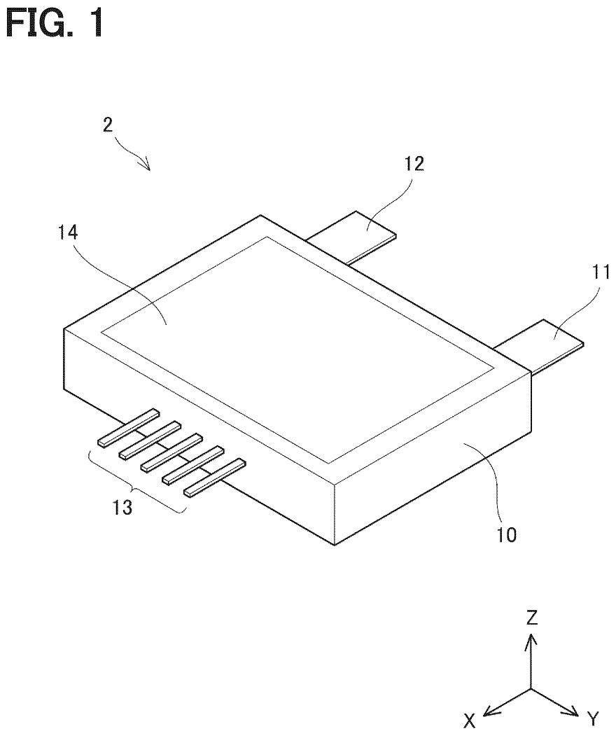

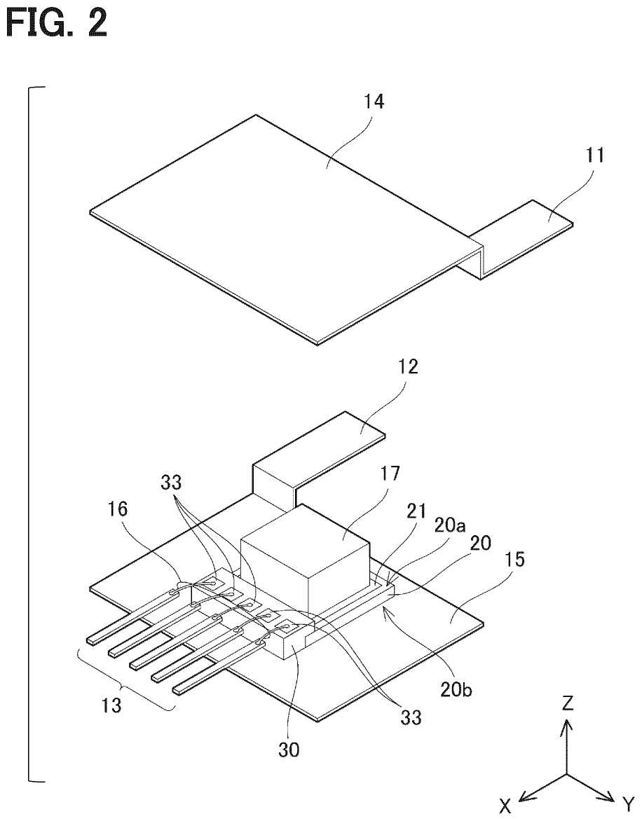

A semiconductor device 2 of a first embodiment will be described with reference to the drawings. FIG. 1 is a perspective view of the semiconductor device 2. FIG. 2 is an exploded perspective view of the semiconductor device 2. The semiconductor device 2 is a device in which a semiconductor element 20 is sealed in a resin package 10. In FIG. 1, the semiconductor element 20 is covered by the resin package 10 and is therefore not visible. FIG. 2 is the exploded perspective view of the semiconductor device 2 in which illustration of the resin package 10 is omitted, and in a state where a first heat dissipation plate 14 is removed.

The semiconductor element 20 is a switching element for power conversion, such as an insulated gate bipolar transistor (IGBT) or a metal oxide semiconductor field effect transistor (MOSFET). The semiconductor element 20 is thus generally referred to as a power semiconductor element. The semiconductor element 20 has a first main surface 20a as a main surface on one side. A first main electrode 21 and a plurality of control electrodes 23 (see FIG. 5) are arranged at the first main surface 20a of the semiconductor element 20. In FIG. 2, the control electrodes 23 are not visible as being hidden behind the terminal substrate 30. The semiconductor element 20 has a second main surface 20b on the other side, as another main surface. A second main electrode 22 is arranged at the second main surface 20b of the semiconductor element 20. The first main electrode 21 and the second main electrode 22 are connected to a source and a drain of the switching element, and thus large currents (for example, 10 amperes or more) flow through the first main electrode 21 and the second main electrode 22.

The lower surface of a copper block 17 is bonded to the first main electrode 21 on the first main surface 20a, and a first heat dissipation plate 14 is bonded to the upper surface of the copper block 17. A first main terminal 11 extends from the edge of the first heat dissipation plate 14. The second main electrode 22 (see FIG. 5) is arranged at the second main surface 20b, and a second heat dissipation plate 15 is bonded to the second main surface 20b including the second main electrode 22. A second main terminal 12 extends from the edge of the second heat dissipation plate 15.

As shown in FIG. 1, the first heat dissipation plate 14 is exposed on a wide surface of the resin package 10 on one side, and the first main terminal 11 extends outward from the resin package 10. Although the second heat dissipation plate 15 is not visible in FIG. 1, the second heat dissipation plate 15 is also exposed on a wide surface of the resin package 10 on the other side, and the second main terminal 12 extends outward from the resin package 10. The first heat dissipation plate 14 has functions as an electric conduction path between the first main electrode 21 of the semiconductor element 20 and the first main terminal 11 as well as a heat sink. Similarly, the second heat dissipation plate 15 has functions as an electric conductive path between the second main electrode 22 of the semiconductor element 20 and the second main terminal 12 as well as a heat sink.

Although not visible in FIGS. 1 and 2, a plurality of control electrodes 23 are exposed on the first main surface 20a of the semiconductor element 20 together with the first main electrode 21. A terminal substrate 30 is mounted on the semiconductor element 20, and a plurality of bonding terminals 33 are exposed on a front surface 30a of the terminal substrate 30. As will be described in detail later, each of the plurality of control electrodes 23 of the semiconductor element 20 is electrically connected to each of the bonding terminals 33. One end of each bonding wire 16 is connected to each bonding terminal 33, and the other end of each bonding wire 16 is connected to each control terminal 13. Note that the terms “front surface” and “back surface” of the terminal substrate 30 are used for convenience to distinguish a pair of surfaces facing in opposite directions from each other. The terms “front surface” and “back surface” may be replaced with “one surface” and “the other surface” as a pair of surfaces facing in opposite directions.

As shown in FIG. 1, the plurality of control terminals 13 extend outward from the resin package 10. The plurality of control electrodes 23 arranged on the first main surface 20a of the semiconductor element 20 are connected to a gate, a sense emitter, a temperature sensor, and the like inside the semiconductor element 20. The bonding wire 16 has electrical conductivity. The plurality of control electrodes 23 of the semiconductor element 20 are electrically connected to the plurality of control terminals 13 via the terminal substrate 30 and the plurality of bonding wires 16.

Although the semiconductor element 20 and the terminal substrate 30 are covered by the resin package 10, external devices can be electrically connected to the first main electrode 21, the control electrodes 23 and the like of the semiconductor element 20 via the main terminals 11 and 12 and the control terminals 13.

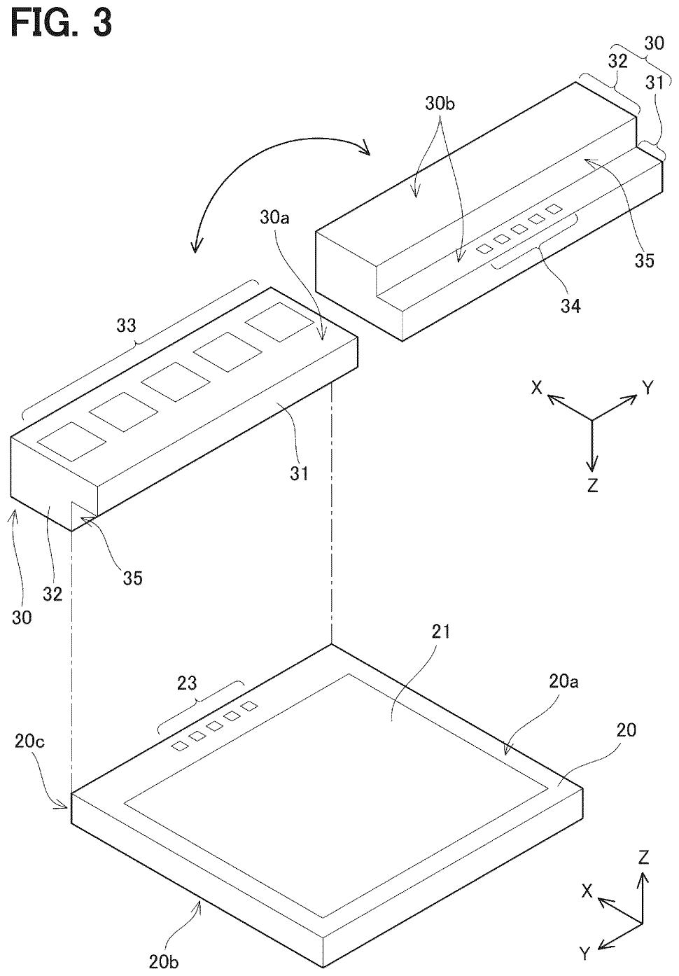

FIG. 3 shows a perspective view in which the terminal substrate 30 is separated from the semiconductor element 20. As described above, the plurality of control electrodes 23 are arranged on the first main surface 20a of the semiconductor element 20 together with the first main electrode 21. As described above, the control electrodes 23 are connected to the gate, the sense emitter, the temperature sensor and the like, and through which only smaller currents than the current flowing through the main electrode flow. Therefore, the area of the control electrode 23 is significantly smaller than the area of the first main electrode 21.

For convenience of explanation, the surface of the terminal substrate 30 facing a +Z direction will be referred to as a front surface 30a, and the surface facing a −Z direction will be referred to as a back surface 30b. In a right upper area in FIG. 3, the terminal substrate 30, which is turned upside down from the terminal substrate 30 shown on the left side, is shown.

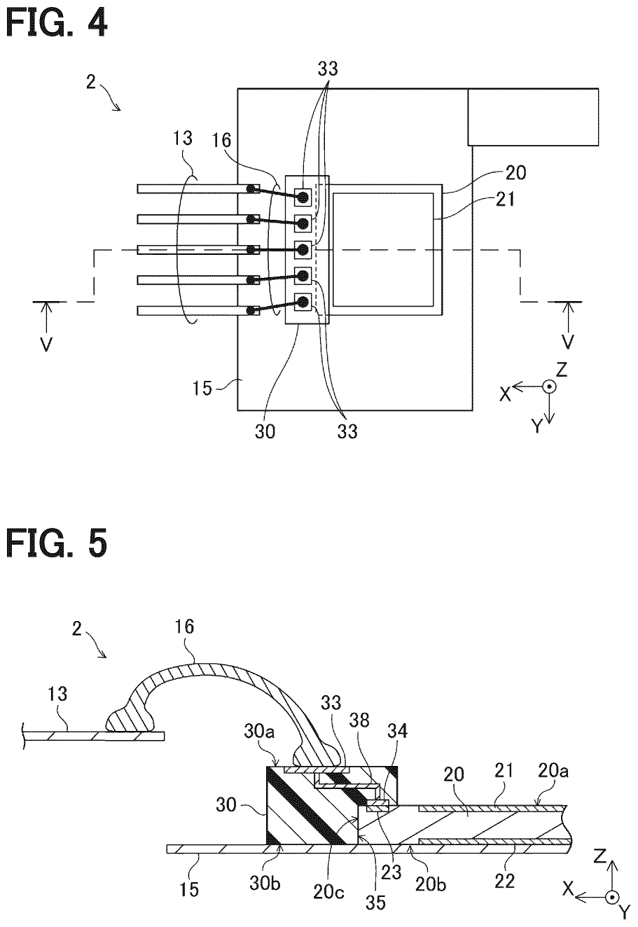

FIG. 4 is a plan view of the semiconductor device 2, and FIG. 5 is a cross-sectional view taken along a line V-V in FIG. 4. However, in FIG. 4, illustrations of the resin package 10, the first heat dissipation plate 14, and the copper block 17 are omitted. In FIG. 5, illustration of the internal structure of the semiconductor element 20 is omitted. The structure of the terminal substrate 30 will be described in detail with reference to FIGS. 3 to 5.

The plurality of bonding terminals 33 are arranged on the front surface 30a of the terminal substrate 30, and the plurality of relay terminals 34 are arranged on the back surface 30b of the terminal substrate 30. The plurality of bonding terminals 33 are correspondingly and electrically connected to the plurality of relay terminals 34 inside the terminal substrate 30.

The terminal substrate 30 includes a thin plate portion 31 having a small thickness and a thick plate portion 32 having a large thickness. The thickness of the thin plate portion 31 is smaller than the thickness of the thick plate portion 32. The plurality of relay terminals 34 are arranged on the back surface 30b of the thin plate portion 31. On the back surface 30b of the terminal substrate 30, the boundary between the thin plate portion 31 and the thick plate portion 32 forms a step 35.

The terminal substrate 30 is bonded to the semiconductor element 20 such that each of the plurality of relay terminals 34 is in contact with and is electrically connected to each of the plurality of control electrodes 23. In this case, the terminal substrate 30 is fixed to the semiconductor element 20 so that a side surface 20c of the semiconductor element 20 abut to the step 35, in particular, to the side surface of the step (see FIG. 5). In other words, the corner between the first main surface 20a and the side surface 20c of the semiconductor element 20 is in contact with the corner of the step 35.

Each of the plurality of relay terminals 34 is arranged so as to face each of the plurality of control electrodes 23 when the side surface 20c of the semiconductor element 20 is in contact with the step 35. When the terminal substrate 30 is attached to the semiconductor element 20 so that the side surface 20c is in contact with the step 35, each of the plurality of relay terminals 34 comes into contact with each of the plurality of control electrodes 23 and is electrically connected. The step 35 serves to accurately position the terminal substrate 30 with respect to the semiconductor element 20 at a target position.

The bonding wire 16 is generally made of aluminum and has a diameter of about 500 micrometers (μm). As shown in FIG. 5, since the tip of the bonding wire 16 (i.e., the tip bonded to the bonding terminal 33) is melted by heat, the tip is larger than the diameter. As best shown in FIGS. 3 through 5, the bonding terminal 33 has a sufficient area to secure the bonding wire 16. In other words, the area of the tip of the bonding terminal 33 is larger than the cross-sectional area of the bonding wire 16. On the other hand, since the terminal substrate 30 is accurately positioned with respect to the semiconductor element 20 by the step 35, the control electrode 23 and the relay terminal 34 are reliably in contact with each other even if their areas are small. The area of the bonding terminal 33 is significantly larger than the areas of the control electrode 23 and the relay terminal 34. In other words, the areas of the control electrode 23 and the relay terminal 34 are smaller than the area of the bonding terminal 33.

In the semiconductor device 2 of the first embodiment, the terminal substrate 30 ensures the bonding terminals 33 having sufficient areas for bonding the bonding wires 16, as well as enables to reduce the control electrodes 23 provided on the first main surface 20a of the semiconductor element 20 in size. As a result, the main surface of the semiconductor element 20 can be reduced in size. That is, the semiconductor element 20 can be reduced in size.

As shown in FIG. 5, the bonding terminals 33 provided on the front surface 30a of the terminal substrate 30 and the relay terminals 34 provided on the back surface 30b of the terminal substrate 30 are connected to each other through conductive patterns 38 provided inside the terminal substrate 30.

Most part of the bonding terminal 33 is arranged in the thick plate portion 32 of the terminal substrate 30, and the relay terminal 34 is arranged in the thin plate portion 31. The thin plate portion 31 is bonded to the first main surface 20a of the semiconductor element 20. As shown in FIG. 5, the back surface 30b of the thick plate portion 32 is flush with the second main surface 20b of the semiconductor element 20, and both the back surface 30b and the second main surface 20b are in contact with the flat second heat dissipation plate 15. The back surface 30b of the terminal substrate 30 is in contact with the second heat dissipation plate 15 in a state where the terminal substrate 30 is bonded to the semiconductor element 20. Therefore, when the bonding wires 16 are bonded to the bonding terminals 33, the terminal substrate 30 will not be displaced relative to the semiconductor element 20.

### (First Modification)

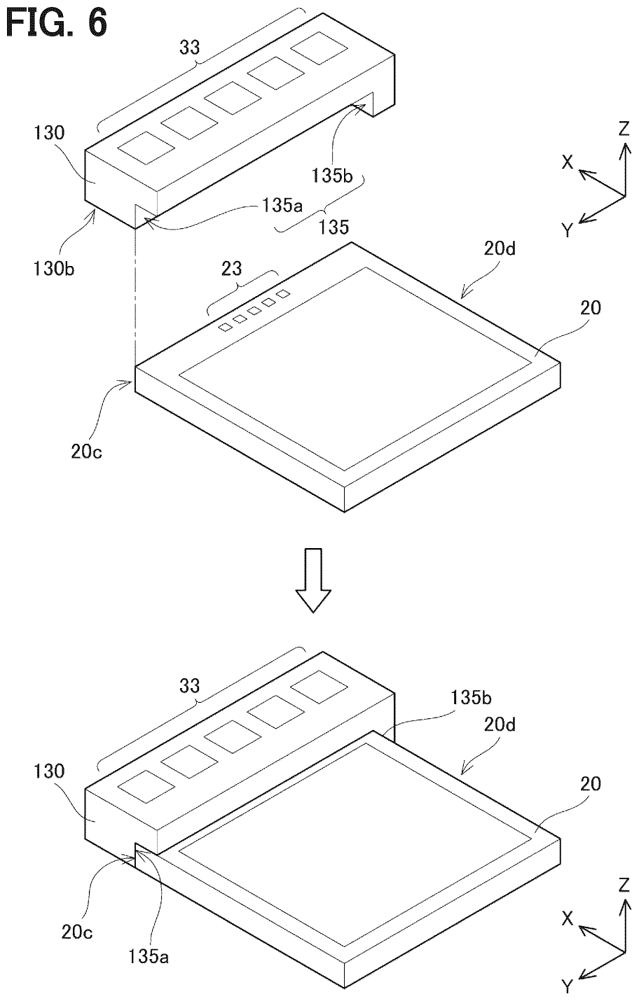

FIG. 6 shows a perspective view of a terminal substrate 130 as a first modification. The terminal substrate 130 has a step 135 on a back surface 130b, and the step 135 has side surfaces 135a and 135b along two directions. The side surface 135a and the side surface 135b are orthogonal to each other. The side surface 135a and the side surface 135b of the step 135 face the −X direction and the −Y direction of the coordinate system in the drawing, respectively. When the terminal substrate 130 is attached to the semiconductor element 20, the side surfaces 135a and 135b of the step 135 abut against the side surfaces 20c and 20d of the semiconductor element 20, respectively. The side surface 20d intersects the side surface 20c. Since the terminal substrate 130 has the step 135 with the side surfaces 135a and 135b along the two directions, the terminal substrate 130 can be accurately positioned with respect to the semiconductor element 20 in two orthogonal directions.

Instead of having the second side surface 135b on the step 135, the second heat dissipation plate 15 may have a protruding guide. The surface of the terminal substrate 30 and the surface of the semiconductor element 20 of the first embodiment respectively facing the Y direction are pressed against the protruding guide. Thus, the terminal substrate 30 can be accurately positioned with respect to the semiconductor element 20 also in the Y direction.

### (Second Modification)

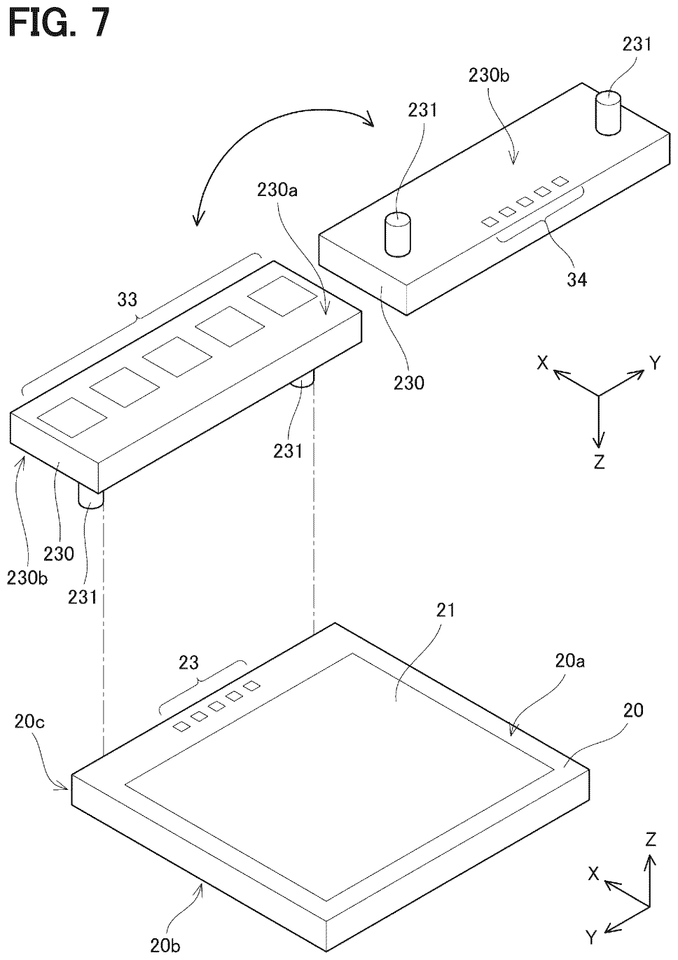

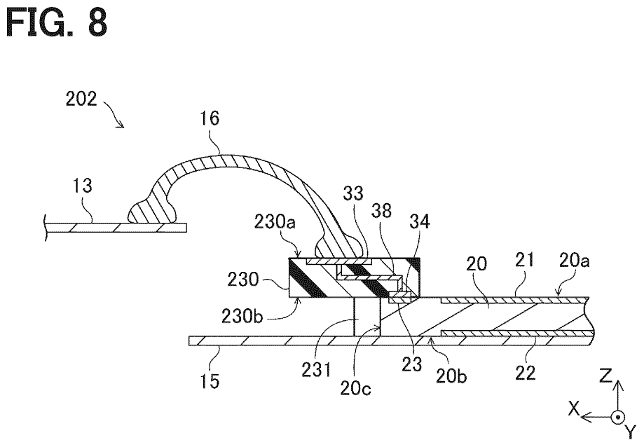

A terminal substrate 230 as a second modification will be described with reference to FIGS. 7 and 8. FIG. 7 is a perspective view of the terminal substrate 230 and the semiconductor element 20. FIG. 8 is a cross-sectional view of a semiconductor device 202 to which the terminal substrate 230 is attached. In the upper right area of FIG. 7, the terminal substrate 230 is illustrated as a perspective view turned upside down from the one shown on the left side. FIG. 7 corresponds to FIG. 3, and FIG. 8 corresponds to FIG. 5.

The terminal substrate 230 includes a plurality of protrusions 231, instead of having the thick plate portion 32 of the terminal substrate 30 of the first embodiment. In the right upper area of FIG. 7, the terminal substrate 230 is illustrated so that the back surface 230b faces upward. The plurality of bonding terminals 33 are arranged on a front surface 230a of the terminal substrate 230, and the plurality of relay terminals 34 are arranged on the back surface 230b. The bonding terminals 33 are correspondingly and electrically connected to the relay terminals 34 through the conductive patterns 38 inside the terminal substrate 230.

The plurality of protrusions 231 are provided on the back surface 230b of the terminal substrate 230. The side surface of the protrusion 231 serves as the step 35 of the terminal substrate 30 of the first embodiment. More precisely, the height difference between the back surface 230b of the terminal substrate 230 and the tip surface of the protrusion 231 corresponds to the step.

When the terminal substrate 230 is attached to the semiconductor element 20, the side surface of the protrusion 231, which corresponds to the side surface of the step, is brought into contact with the side surface 20c of the semiconductor element 20. By bringing the side surface of the protrusion 231 into contact with the side surface 20c of the semiconductor element 20, the terminal substrate 230 can be accurately positioned relative to the semiconductor element 20 in the X direction.

Other features regarding the semiconductor devices 2 (202) of the embodiments will be described hereinafter. The terminal substrate 30 (130, 230) is made of the same material as the resin package 10 covering the semiconductor element 20. The material of the resin package 10 is typically polyimide or polyamide. By making the terminal substrate 30 (130, 230) from the same material as the resin package 10, the stress generated near the boundary between the resin package 10 and the terminal substrate 30 (130, 230) can be reduced when the resin package 10 is formed by injection molding.

The points to be noted regarding the techniques of the embodiments described above will be described. A plurality of terminal substrates may be attached to one semiconductor element. A plurality of control electrodes may be dispersedly arranged at a plurality of locations on the first main surface of the semiconductor element 20.

Although specific examples of the present disclosure have been described in detail above, these are merely examples and do not limit the scope of claims. The techniques described in the claims include various modifications and modifications of the specific examples illustrated above. The technical elements described in the present description or the drawings exhibit technical usefulness alone or in various combinations, and are not limited to the combinations described in the present description at the time of filing. In addition, the techniques illustrated in the present specification or the drawings can achieve multiple purposes at the same time, and achieving one of the purposes itself has technical usefulness.

What is claimed is:

1. A semiconductor device comprising:
a semiconductor element having a main electrode and a control electrode on a first main surface; and
a terminal substrate having a bonding terminal to which a wire is to be bonded on a front surface and a relay terminal on a back surface, the bonding terminal and the relay terminal being electrically connected to each other, wherein
the bonding terminal has an area larger than an area of the control electrode,
the terminal substrate is bonded to the semiconductor element so that the control electrode and the relay terminal are in contact with each other,
the terminal substrate has a step on the back surface, and
a side surface of the semiconductor element is in contact with the step.

2. The semiconductor device according to claim 1, wherein
the terminal substrate has a thin plate portion including the relay terminal and a thick plate portion including the bonding terminal,
a thickness of the thin plate portion is smaller than a thickness of the thick plate portion,
a boundary between the thin plate portion and the thick plate portion corresponds to the step, and
the thin plate portion is bonded to the semiconductor element.

3. The semiconductor device according to claim 2, wherein
the back surface of the terminal substrate in the thick plate portion is flush with a second main surface of the semiconductor element.

4. The semiconductor device according to claim 1, wherein
the terminal substrate has a protrusion forming the step on the back surface.

5. The semiconductor device according to claim 1, further comprising:
a resin package that covers the semiconductor element and the terminal substrate, wherein
the resin package and the terminal substrate are made of a same material.
